(19) United States
(12) Patent Application Publication
(10) Pub. No.: US 2024/0357903 A1
(43) Pub. Date: Oct. 24, 2024

(54) DISPLAY DEVICE AND METHOD OF MANUFACTURING THE SAME

(71) Applicant: Samsung Display Co., LTD., Yongin-si (KR)

(72) Inventors: Min Hee PARK, Yongin-si (KR); Kyung Hoon CHAE, Yongin-si (KR); Dae Woo LEE, Yongin-si (KR); So Yeon JOO, Yongin-si (KR); Hyeon Deuk HWANG, Yongin-si (KR)

(73) Assignee: Samsung Display Co., LTD., Yongin-si (KR)

(21) Appl. No.: 18/418,675

(22) Filed: Jan. 22, 2024

(30) Foreign Application Priority Data
Apr. 21, 2023 (KR) 10-2023-0052993

(51) Int. Cl. H10K 59/80; H10K 71/50

(52) U.S. Cl. CPC H10K 59/873; H10K 59/8792; H10K 71/50

(57) ABSTRACT

A display device includes a display panel including a first non-bending area, a bending area extending from the first non-bending area, and a second non-bending area extending from the bending area, an adhesive layer disposed in the first non-bending area, a window connected to the display panel through the adhesive layer, the window including a base substrate, a light blocking pattern disposed on the base substrate, and a protrusion pattern disposed on at least a portion of the light blocking pattern, and a reinforcing layer surrounding at least a portion of the bending area.

### CROSS-REFERENCE TO RELATED APPLICATION(S)

This application claims priority to and benefits of Korean Patent Application No. 10-2023-0052993 filed on Apr. 21, 2023 under 35 U.S.C. § 119, in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

As information technology develops, the importance of a display device, which is a connection medium between a user and information, has been highlighted. In response to this, a use of a display device such as a liquid crystal display device and an organic light emitting display device is increasing.

Recently, as technology is being developed, a display device including a flexible display panel is being developed. A bending area of the display panel that is bent with a selectable curvature may be vulnerable to stress applied to an external impact.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device in which strength outside of a bending area of a display panel is reinforced.

The disclosure provides a method of manufacturing a display device capable of readily and quickly reinforcing strength outside a bending area of a display panel.

According to an embodiment, a display device may include a display panel including a first non-bending area; a bending area extending from the first non-bending area; and a second non-bending area extending from the bending area; an adhesive layer disposed in the first non-bending area; a window connected to the display panel through the adhesive layer, the window including a base substrate; a light blocking pattern disposed on the base substrate; and a protrusion pattern disposed on at least a portion of the light blocking pattern, and connected to the display panel through the adhesive layer; and a reinforcing layer surrounding at least a portion of the bending area.

The reinforcing layer may contact at least a portion of the light blocking pattern.

The reinforcing layer may contact a surface of the protrusion pattern.

The reinforcing layer may contact at least a portion of the first non-bending area.

The reinforcing layer may include an ultraviolet curable resin.

The protrusion pattern and the light blocking pattern may include a same material.

The protrusion pattern may include an ultraviolet curable resin.

The light blocking pattern may overlap the bending area.

According to an embodiment, a method of manufacturing a display device may include providing a display panel including a first non-bending area; a bending area extending from the first non-bending area; and a second non-bending area extending from the bending area; connecting a window to the display panel, wherein the window includes a base substrate; a light blocking pattern disposed on the base substrate; and a protrusion pattern disposed on at least a portion of the light blocking pattern to the display panel; attaching the second non-bending area to a fixing member to upwardly expose the bending area; applying a resin to surround at least a portion of the bending area; and detaching the fixing member.

In the applying of the resin, the resin may be applied to contact at least a portion of the light blocking pattern.

In the applying of the resin, the resin may be applied to contact a surface of the protrusion pattern.

The light blocking pattern may overlap the bending area.

The protrusion pattern may be formed by printing a same material as the light blocking pattern after the light blocking pattern is formed.

The protrusion pattern may be formed by printing a same material as the light blocking pattern in which a portion of the light blocking pattern is masked.

The protrusion pattern may be formed by applying the resin to the light blocking pattern and curing the resin with ultraviolet rays.

A portion of the fixing member to which at least a portion of the second non-bending area is attached may protrude.

The fixing member may be formed of a material having releasability with the resin.

The fixing member may be an open jig.

The fixing member may be a guide film.

The method may further include curing the resin with ultraviolet rays.

According to the embodiments of the disclosure, strength of the bending area of the display panel may be reinforced, and a time consumed in a manufacturing process of the display device may be reduced.

However, effects of the disclosure are not limited to the above-described effects, and may be variously expanded within a range that does not deviate from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a schematic diagram illustrating a display device according to an embodiment.

FIG. 2 is a schematic cross-sectional view of a display device according to an embodiment.

FIG. 3 is a diagram illustrating a method of manufacturing a display device according to an embodiment; and

FIGS. 4, 5, 6, 7, 8, 9, 10, 11 and 12 are schematic diagrams schematically illustrating a method of manufacturing a display device according to an embodiment.

### DETAILED DESCRIPTION OF THE EMBODIMENTS

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art.

In describing the drawings, like reference numerals have been used for like elements. In the accompanying drawings, the dimensions of the structures are enlarged than the actual size in order to clearly explain the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element.

The terminology used herein is for the purpose of describing embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the following description, when a first part is “connected” to a second part, this includes not only the case where the first part is directly connected to the second part, but also the case where a third part is interposed therebetween and they are connected to each other.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would be oriented “above” the other elements. The terms “below” or “beneath” can, therefore, encompass both an orientation of above and below.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the disclosure are described in detail with reference to the accompanying drawings.

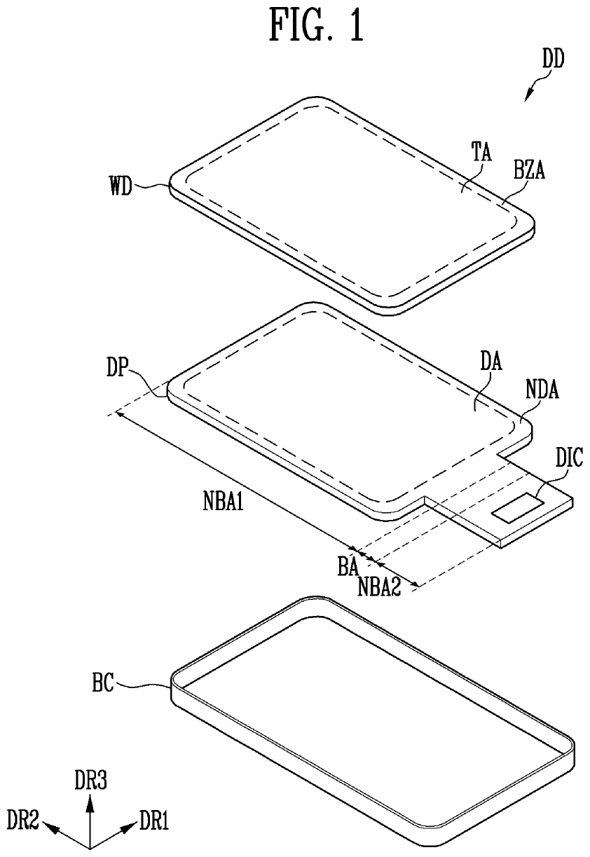

FIG. 1 is a schematic diagram illustrating a display device DD according to an embodiment.

Referring to FIG. 1, the display device DD may include a display panel DP, a window WD, and a bracket BC.

The display device DD may be a device that is activated according to an electrical signal and displays an image. For example, the display device DD may be used as a display screen of a portable electronic device such as a mobile phone, a smart phone, a tablet personal computer (PC), a mobile communication terminal, an electronic notebook, an electronic book, a portable multimedia player (PMP), a navigation device, and an ultra mobile PC (UMPC). The display device DD may be used as a display screen of various products such as a television, a notebook computer, a monitor, a billboard, and Internet of things (IOT).

The display device DD may have various shapes such as a rectangle, a circle, and a polygon on a plane.

The display device DD may be flexible. “Flexible” may mean a property of being able to be bent, and may include everything from a completely foldable structure to a structure that may be bent at a level of several nanometers. For example, the flexible display device DD may include a curved display device or a foldable display device. However, the disclosure is not limited thereto, and the display device DD may be rigid.

The display device DD may detect an external input applied from an outside. The external input may have various forms such as pressure, temperature, and light provided from the outside. The external input may include not only a contact to the display device DD, for example, a user's hand or a pen, but also an input applied in close proximity to the display device DD (for example, hovering).

The display panel DP may display an image on a front surface. The display panel DP may be a light emitting display panel. For example, the display panel DP may be an organic light emitting display panel, a quantum dot light emitting display panel, a micro LED display panel, or a nano LED display panel.

The display panel DP may include a first non-bending area NBA1, a second non-bending area NBA2, and a bending area BA. The first non-bending area NBA1, the bending area BA, and the second non-bending area NBA2 may be arranged or disposed along a second direction DR2. The bending area BA may extend along the second direction DR2 from the first non-bending area NBA1. The second non-bending area NBA2 may extend along the second direction DR2 from the bending area BA.

A width of the first non-bending area NBA1 defined along a first direction DR1 may be greater than a width of the bending area BA and a width of the second non-bending area NBA2. However, shapes of the first non-bending area NBA1, the bending area BA, and the second non-bending area NBA2 are not limited to the shown embodiment.

The bending area BA may be an area bent while having a selectable curvature. In a manufacturing process of the display device DD, the bending area BA may be bent so that the second non-bending area NBA2 overlaps the first non-bending area NBA1 on a plane. For example, the second non-bending area NBA2 may be disposed on a rear surface of the display panel DP corresponding to the first non-bending area NBA1, by bending the bending area BA.

The display panel DP may include a display area DA and a non-display area NDA. The display area DA of the display panel DP may be defined within the first non-bending area NBA1.

The display area DA may be an area activated according to an electrical signal and may be an area where an image is displayed. Pixels for displaying an image may be disposed in the display area DA. The display area DA may correspond to a transmission area TA. In the specification, “an area/a portion and an area/a portion correspond” means “overlap each other” and is not limited to having the same area and/or the same shape. The image displayed in the display area DA may be viewed from the outside through the transmission area TA.

The non-display area NDA may be an area in which an image is not displayed. At least one circuit, pad, line, or the like for driving the pixels may be disposed in the non-display area NDA. The non-display area NDA may be adjacent to the display area DA. For example, the non-display area NDA may surround the display area DA. However, the non-display area NDA is not limited thereto, and the non-display area NDA may be defined in various shapes.

The non-display area NDA may correspond to a remaining area of the first non-bending area NBA1 excluding the display area DA overlapping the first non-bending area NBA1, the bending area BA, and the second non-bending area NBA2.

The non-display area NDA may correspond to a bezel area BZA. Configurations of the display panel DP disposed in the non-display area NDA may be prevented from being viewed from the outside by the bezel area BZA.

A driving chip DIC may be disposed in the second non-bending area NBA2 of the display panel DP. The driving chip DIC may be manufactured in a form of an integrated circuit chip and mounted in the second non-bending area NBA2. A printed circuit board or the like including electronic elements mounted on a substrate may be disposed in the second non-bending area NBA2.

The window WD may form an appearance of the display device DD. The window WD may be disposed on the front surface of the display panel DP to protect the display panel DP. The image displayed on the display panel DP may pass through the window WD and may be recognized by a user.

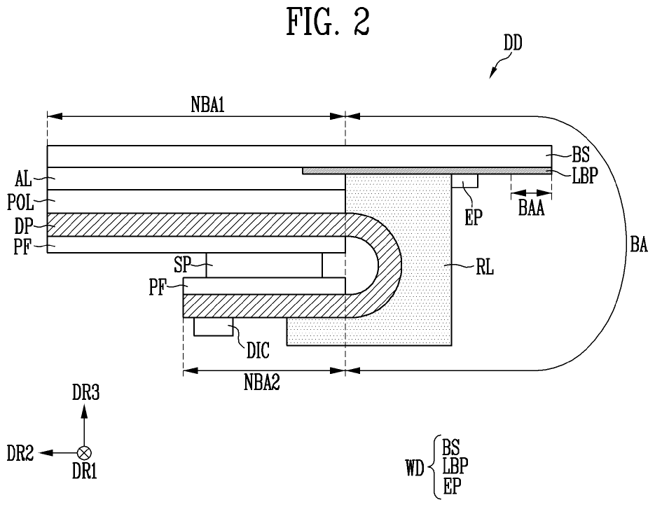

The window WD may be attached on the display panel DP by an adhesive layer AL (refer to FIG. 2).

The window WD may include an optically transparent insulating material. For example, the window WD may include glass, sapphire, or plastic. The window WD may have a single-layer structure or a multi-layer structure. The window WD may further include functional layers such as an anti-fingerprint layer, a phase control layer, and a hard coating layer disposed on an optically transparent substrate.

The window WD may include the transmission area TA and the bezel area BZA.

The transmission area TA may be an area that transmits incident light. The transmission area TA may have a shape corresponding to that of the display area DA of the display panel DP. For example, the transmission area TA may overlap the entire surface or at least a portion of the display area DA of the display panel DP. The image displayed in the display area DA of the display panel DP may be viewed from the outside through the transmission area TA.

The bezel area BZA may be an area of which light transmittance is relatively low compared to the transmission area TA. The bezel area BZA may define a shape of the transmission area TA. For example, the bezel area BZA may be adjacent to the transmission area TA and surround the transmission area TA. However, the bezel area BZA is not limited thereto, and the bezel area BZA may be defined in various shapes.

The bezel area BZA may be an area having a selectable color and blocking light. The bezel area BZA may have a shape corresponding to the non-display area NDA of the display panel DP. For example, the bezel area BZA may overlap the entire surface or at least a portion of the non-display area NDA of the display panel DP. The bezel area BZA may cover the non-display area NDA of the display panel DP to block the non-display area NDA from being viewed from the outside.

The bracket BC may be connected to the window WD to form the appearance of the display device DD, and may provide an internal space capable of receiving configurations of the display device DD. For example, the bracket BC may be disposed below the display panel DP to receive the display panel DP. The bracket BC may protect the display panel DP by absorbing shock applied from the outside and blocking a foreign substance, moisture, or the like from penetrating into the display panel DP. The bracket BC may be provided in a form in which receiving members are combined.

The display device DD may further include an electronic module including various functional modules for operating the display panel DP, a power supply module supplying necessary power to the display device DD, and the like within the spirit and the scope of the disclosure.

FIG. 2 is a schematic cross-sectional view of a display device DD according to an embodiment. FIG. 2 is a schematic cross-sectional view of the display device DD in which the bending area BA of the display panel DP is bent about an imaginary axis extending in the first direction DR1.

Referring to FIG. 2, the window WD may include a base substrate BS, a light blocking pattern LBP, and a protrusion pattern EP. The base substrate BS may include an optically transparent insulating material. For example, the base substrate BS may include glass, sapphire, or plastic. When the base substrate BS is a plastic substrate, the base substrate BS may include a polymer material. For example, the base substrate BS may be made of polyimide (PI), polyacrylate (PA), polymethylmethacrylate (PMMA), polycarbonate (PC), polyethylene naphthalate (PEN), polyvinylidene chloride (PVC), polyvinylidene difluoride (PVDF), polystyrene (PS), ethylene-vinyl alcohol copolymer or a combination thereof.

The light blocking pattern LBP may be a color layer disposed on one surface or a surface of the base substrate BS. For example, the light blocking pattern LBP may be disposed on a lower surface of the base substrate BS. The light blocking pattern LBP may be formed by depositing, printing, or coating a material in which a dye or a pigment is mixed on the base substrate BS. The light blocking pattern LBP may correspond to the bezel area BZA (refer to FIG. 1) of the window WD. One area or an area of the base substrate BS which does not overlap the light blocking pattern LBP may correspond to the transmission area TA of the window WD (refer to FIG. 1).

The light blocking pattern LBP may include a material having a selectable color. For example, the light blocking pattern LBP may be formed of an organic light blocking material or an inorganic light blocking material including a black pigment or a black dye. However, the light blocking pattern LBP is not limited thereto, and the light blocking pattern LBP may be formed of an organic light blocking material or an inorganic light blocking material including a colored pigment or a colored dye. A color of the light blocking pattern LBP may be defined as a color of the bezel area BZA (refer to FIG. 1).

The light blocking pattern LBP may prevent configurations of the display device DD disposed to overlap the light blocking pattern LBP from being viewed from the outside. For example, the bending area BA of the display panel DP may overlap the light blocking pattern LBP on a plane. At least a portion of the first non-bending area NBA1 and at least a portion of the second non-bending area NBA2 of the display panel DP may overlap the light blocking pattern LBP on a plane. The light blocking pattern LBP may prevent configurations (for example, signal lines) of the display panel DP disposed in the bending area BA, at least a portion of the first non-bending area NBA1, and at least a portion of the second non-bending area NBA2 from being viewed from the outside due to reflection of external light.

The protrusion pattern EP may be disposed on at least a portion of the light blocking pattern LBP. In an embodiment, the protrusion pattern EP may be disposed on the light blocking pattern LBP which does not overlap the bending area BA of the display panel DP. However, the protrusion pattern EP is not limited thereto, and the protrusion pattern EP may be disposed on the light blocking pattern LBP to overlap at least a portion of the bending area BA of the display panel DP.

In an embodiment, the protrusion pattern EP may serve to control a shape (or size) of a reinforcing layer RL. For example, the protrusion pattern EP may control the shape of the reinforcing layer RL to sufficiently reinforce strength of the bending area BA of the display panel DP. For example, the shape of the reinforcing layer RL may be determined according to a position of the protrusion pattern EP in the manufacturing process of the display device DD.

The protrusion pattern EP may prevent the reinforcing layer RL from invading an area BAA where the bracket BC (refer to FIG. 1) is assembled (or attached). At this time, an adhesive such as a tape may be provided in the area BAA where the bracket BC is assembled, and the bracket BC may be attached to the window WD through the tape. For example, the protrusion pattern EP may serve as a dam to prevent the reinforcing layer RL from extending (or expanding) to the area BAA where the bracket BC is assembled. Accordingly, a sufficient space may be secured in the area BAA where the bracket BC is assembled. Thus, the bracket BC may be readily assembled and a freedom degree of the shape (or design) of the bracket BC may be increased. The area BAA where the bracket BC is assembled shown in FIG. 2 is an example, and the disclosure is not limited thereto. For example, the area BAA where the bracket BC is assembled may be adjacent to the protrusion pattern EP.

The protrusion pattern EP may include the same material or a similar material as the light blocking pattern LBP. For example, the protrusion pattern EP may include a material having the same selectable color as the light blocking pattern LBP. When the protrusion pattern EP may include the same material or a similar material as the light blocking pattern LBP, the protrusion pattern EP may correspond to a protruding portion of the light blocking pattern LBP. The protrusion pattern EP may include a material different from that of the light blocking pattern LBP. For example, the protrusion pattern EP may include resin (RE, refer to FIG. 8). At this time, the resin RE may be an ultraviolet curable resin (UV resin). An example method of forming the protrusion pattern EP is described later.

The display device DD may include the adhesive layer AL. The adhesive layer AL may be disposed to overlap the first non-bending area NBA1 of the display panel DP. The window WD may be connected to the display panel DP by the adhesive layer AL. The adhesive layer AL may be disposed on a polarization layer POL, or may be disposed on the display panel DP when the polarization layer POL is omitted. The adhesive layer AL may include an adhesive member such as optical clear adhesive (OCA) or pressure sensitive adhesive (PSA).

The display device DD may include the reinforcing layer RL. The reinforcing layer RL may be disposed to surround at least a portion of the bending area BA of the display panel DP.

In an embodiment, the reinforcing layer RL may be disposed to surround at least a portion of an outer surface of the bending area BA of the display panel DP. Accordingly, external strength of the bending area BA of the display panel DP may be reinforced, and thus external impact acting on the bending area BA of the display panel DP may be blocked or reduced. Furthermore, as the external strength of the bending area BA of the display panel DP is reinforced, a cap for protecting the bending area BA of the display panel DP may be unnecessary during a transfer process of the display panel DP, a manufacturing cost of the display device DD may be reduced.

In an embodiment, the reinforcing layer RL may be disposed to contact at least a portion of the light blocking pattern LBP. Accordingly, the reinforcing layer RL may be formed to be thick, and thus may sufficiently reinforce the strength of the outside of the bending area BA of the display panel DP.

In an embodiment, the reinforcing layer RL may be disposed to contact one surface or a surface of the protrusion pattern EP. Accordingly, the reinforcing layer RL may reinforce the strength of the outside of the bending area BA of the display panel DP without invading the area BAA where the bracket BC (refer to FIG. 1) is assembled.

In an embodiment, the reinforcing layer RL may be disposed on at least a portion of the second non-bending area NBA2 of the display panel DP. Accordingly, an external impact applied to the bending area BA through the second non-bending area NBA2 of the display panel DP may be blocked or reduced.

The reinforcing layer RL may include resin RE (refer to FIG. 8). In an embodiment, the reinforcing layer RL may include an ultraviolet curable resin (UV resin). The reinforcing layer RL may be formed by filling the ultraviolet curable resin (UV resin) and curing the ultraviolet curable resin with ultraviolet rays.

The display device DD may include a protective film PF and a spacer SP.

The protective film PF may be disposed on at least a portion of an inner surface of the display panel DP. For example, the protective film PF may be disposed on an inner surface of the first non-bending area NBA1 of the display panel DP and an inner surface of the second non-bending area NBA2 of the display panel DP. For example, the protective film PF may not be disposed on an inner surface of the bending area BA of the display panel DP. Accordingly, the bending area BA of the display panel DP may be readily bent while the protection film PF protects the display panel DP. The protective film PF may include a plastic material having flexibility. For example, the protective film PF may include polyimide (PI) or polyethylene terephthalate (PET). However, a material of the protective film PF is not limited to the above-described example.

The spacer SP may be disposed between portions of the protective film PF. For example, the spacer SP may be disposed between a portion of the protective film PF disposed on the inner surface of the first non-bending area NBA1 of the display panel DP and a portion of the protective film PF disposed on the inner surface of the second non-bending area NBA2 of the display panel DP. The spacer SP may be disposed in a spaced apart space between portions of the protective film PF to support the protective film PF and the second non-bending area NBA2 of the display panel DP.

The display device DD may further include the polarization layer POL. The polarization layer POL may be disposed to overlap the first non-bending area NBA1 of the display panel DP. The polarization layer POL may reduce reflection of external light. For example, when the external light passes through the polarization layer POL, is reflected from an upper portion of the display panel DP, and passes through the polarization layer POL again, as the external light passes through the polarization layer POL twice, a phase of the external light may change. As a result, since a phase of reflected light is different from the phase of the external light entering the polarization layer POL, destructive interference may occur. Accordingly, the reflection of the external light may be reduced, and thus the visibility of the display device DD may be improved.

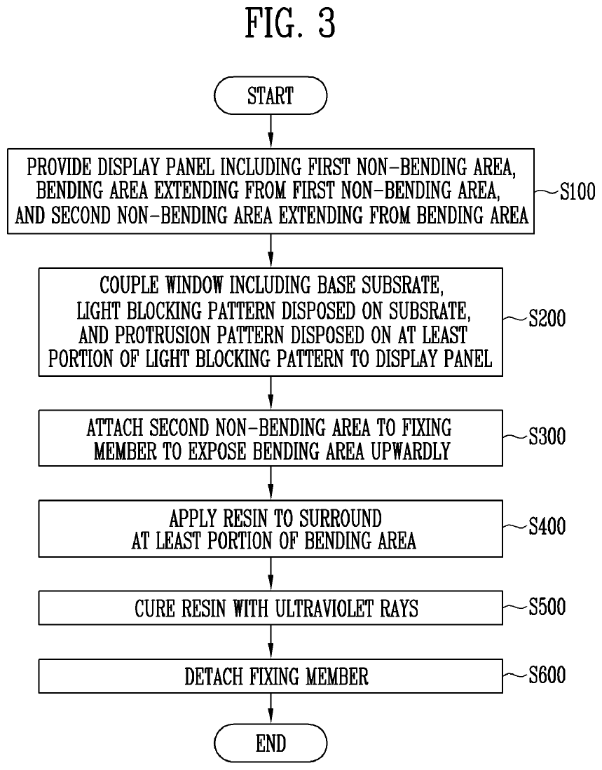

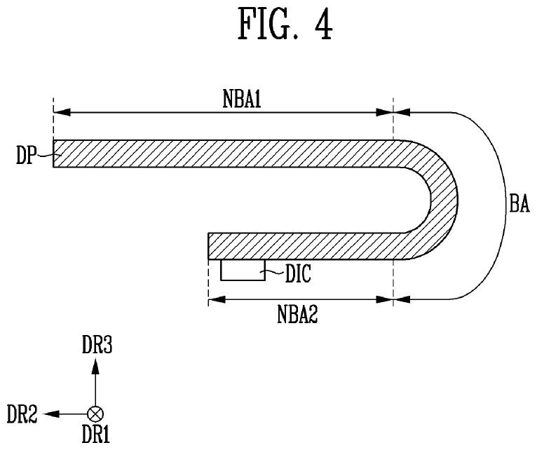

FIG. 3 is a diagram illustrating a method of manufacturing a display device DD according to an embodiment. FIGS. 4 to 12 are schematic diagrams schematically illustrating a method of manufacturing a display device DD according to an embodiment. When describing FIGS. 3 to 12, a description of a content overlapping that described with reference to FIGS. 1 and 2 is omitted or simplified.

Referring to FIGS. 3 and 4, first, the display panel DP including the first non-bending area NBA1, the bending area BA extending from the first non-bending area NBA1, and the second non-bending area NBA2 extending from the bending area BA is provided (S100).

The display panel DP may include a display substrate, a display element layer disposed on the display substrate, and an encapsulation layer disposed on the display element layer.

The display substrate may include a base substrate, and insulating layers, functional layers, conductive layers, and the like disposed on the base substrate. For example, the conductive layer may include gate lines, data lines, and other signal lines. The conductive layer may include pads connected to the above-described lines.

The display element layer may include insulating layers, functional layers, conductive layers, and the like within the spirit and the scope of the disclosure. For example, the functional layer may include an organic light emitting diode.

The encapsulation layer may be disposed on the display element layer to protect the display element layer. According to a type of the display panel DP, the encapsulation layer may be omitted or may be replaced with another display substrate.

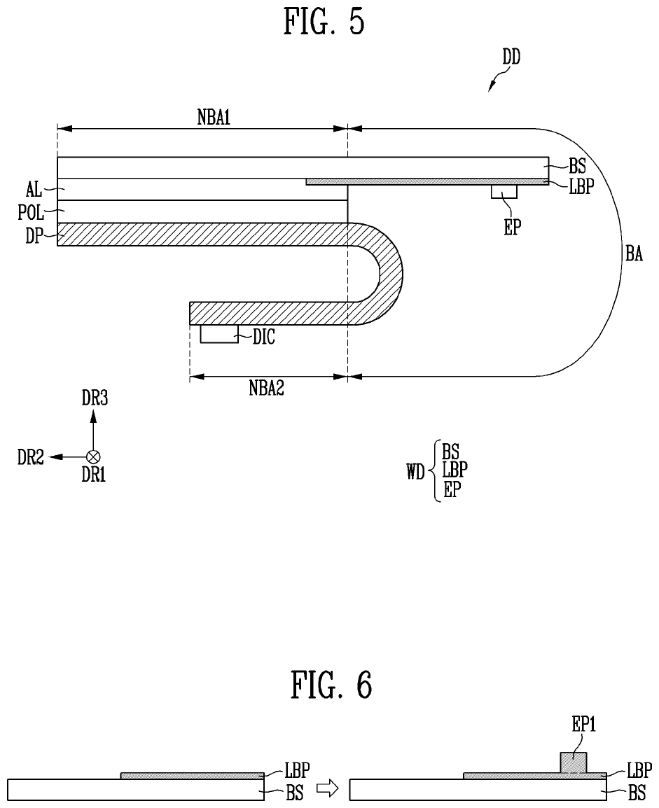

Referring to FIGS. 3 and 5, the window WD may be connected to the display panel DP (S200). The window WD may be connected to the display panel DP through the adhesive layer AL. The window WD may include the base substrate BS, the light blocking pattern LBP disposed on the base substrate BS, and the protrusion pattern EP disposed on at least a portion of the light blocking pattern LBP. Step S200 may be referred to as a lamination process.

Referring to FIGS. 5 to 8, the protrusion pattern EP may include protrusion patterns EP1, EP2, and EP3 formed in different methods.

Referring to FIG. 6, the protrusion pattern EP1 according to an embodiment may be formed by depositing, printing, or coating the same material or a similar material as the light blocking pattern LBP on at least a portion of the light blocking pattern LBP after the light blocking pattern LBP is formed. For example, the protrusion pattern EP1 according to an embodiment may be formed by additionally depositing, printing, or coating the light blocking pattern LBP. As described above, the protrusion pattern EP1 according to an embodiment may correspond to a protruding portion of the light blocking pattern LBP.

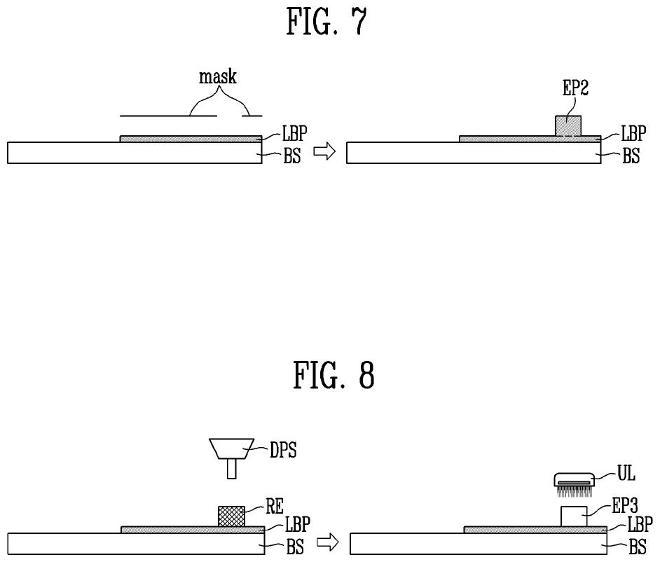

Referring to FIG. 7, the protrusion pattern EP2 according to an embodiment may be formed by masking at least a portion of the light blocking pattern LBP in a process of forming the light blocking pattern LBP. For example, the protrusion pattern EP2 according to an embodiment may be formed by depositing, printing, or coating the light blocking pattern LBP in a state in which at least a portion of the light blocking pattern LBP is masked with a mask or the like within the spirit and the scope of the disclosure. Different from FIG. 6, the protrusion pattern EP2 according to an embodiment may be formed by forming a step difference in the light blocking pattern LBP during the process of forming the light blocking pattern LBP. As described above, the protrusion pattern EP2 according to an embodiment may correspond to the protruding portion of the light blocking pattern LBP.

Referring to FIG. 8, the protrusion pattern EP3 according to an embodiment may be formed by applying the resin RE. For example, the resin RE may be an ultraviolet curable resin (UV resin). The protrusion pattern EP3 according to an embodiment may be formed by applying the resin RE to at least a portion of the light blocking pattern LBP using a dispenser DPS and curing the resin RE using an ultraviolet lamp UL.

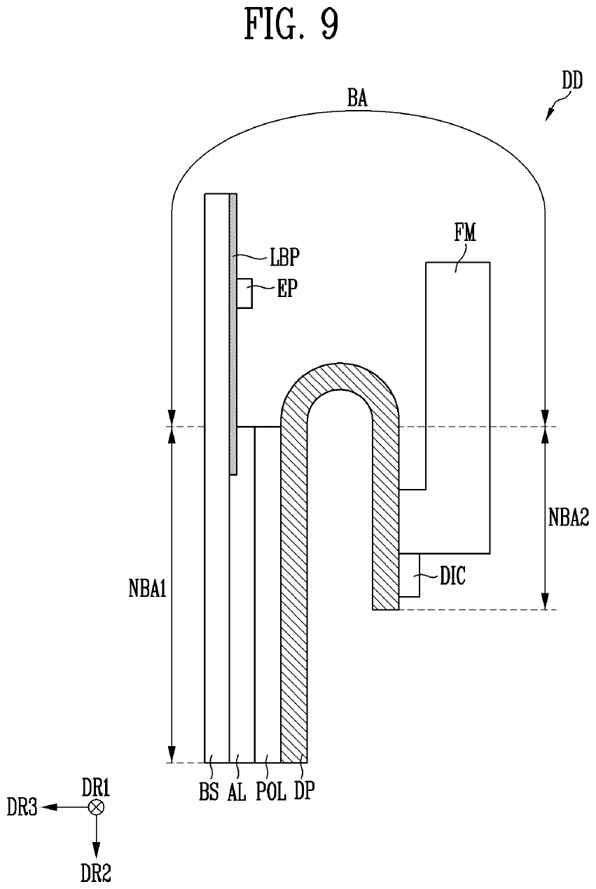

Referring to FIGS. 3 and 9, the second non-bending area NBA2 of the display panel DP may be attached to a fixing member FM to expose the bending area BA of the display panel DP upwardly (S300). When the bending area BA of the display panel DP is exposed upwardly, the resin RE (refer to FIG. 8) may be readily applied in a non-contact manner. Since ultraviolet rays may be directly irradiated, an ultraviolet curable resin (UV resin) may be used without limitation. Accordingly, a process time may be shortened compared to a manufacturing process using a natural curing type resin or a heat curing type resin.

One side or a side of the fixing member FM may be opened to expose the bending area BA of the display panel DP upwardly. In an embodiment, the fixing member FM may be an open jig. In an embodiment, the fixing member FM may be a guide film. When the fixing member FM is a guide film, the fixing member FM may be advantageous in terms of cost.

At least a portion of the fixing member FM to which the display panel DP is attached may protrude. In an embodiment, at least a portion of the fixing member FM to which the second non-bending area NBA2 of the display panel DP is attached may protrude. For example, the protruding portion of the fixing member FM may contact at least a portion of the second non-bending area NBA2 of the display panel DP. Accordingly, the fixing member FM may serve as a mold for forming a space where the resin RE is applied while fixing the display panel DP. The protruding portion of the fixing member FM may be spaced apart from the driving chip DIC and contact at least a portion of the second non-bending area NBA2 of the display panel DP.

In an embodiment, the fixing member FM may be formed of a material having releasability with the resin RE. This is to facilitate attachment and detachment of the fixing member FM without affecting a shape of the resin RE. For example, the fixing member FM may include at least one of Teflon™ and silicon, but the disclosure is not limited thereto.

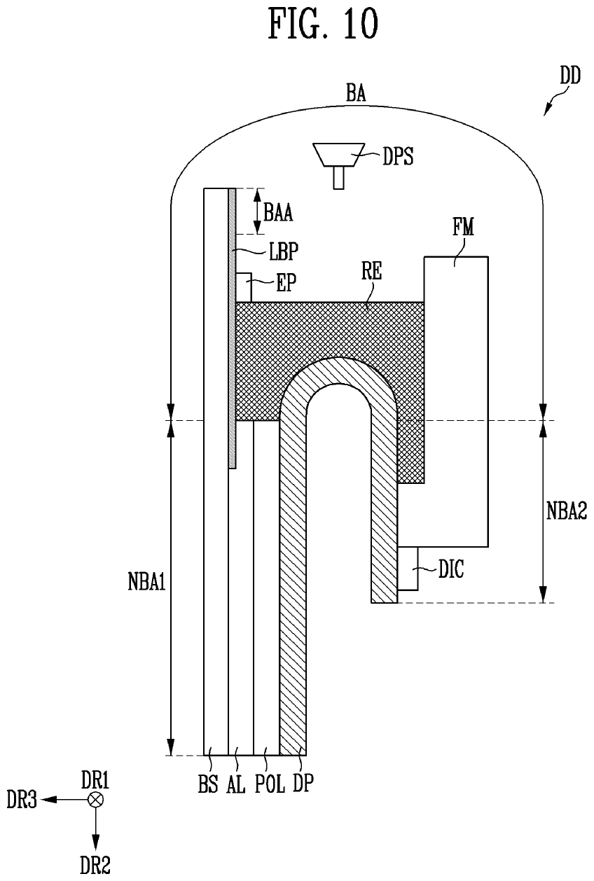

Referring to FIGS. 3 and 10, the resin RE may be applied to surround at least a portion of the bending area BA of the display panel DP (S400). For example, the resin RE may be sprayed from the dispenser DPS in a vertical direction to surround at least a portion of an outside of the bending area BA of the display panel DP.

In an embodiment, the resin RE may be applied to contact at least a portion of the light blocking pattern LBP. Accordingly, the resin RE may be applied thickly to sufficiently reinforce the strength of the outside of the bending area BA of the display panel DP.

In an embodiment, the resin RE may be applied to contact one surface or a surface of the protrusion pattern EP. Accordingly, the resin RE may reinforce the strength of the outside of the bending area BA of the display panel DP without invading the area BAA where the bracket BC (refer to FIG. 1) is assembled.

In an embodiment, the resin RE may be applied to at least a portion of the second non-bending area NBA2 of the display panel DP. Accordingly, an external impact applied to the bending area BA through the second non-bending area NBA2 of the display panel DP may be blocked or reduced.

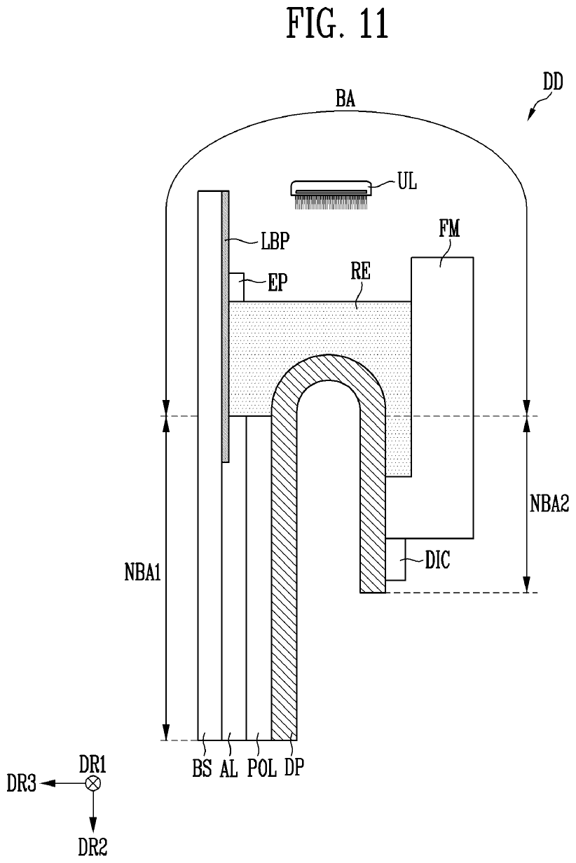

Referring to FIGS. 3 and 11, the resin RE may be cured with ultraviolet rays (S500). For example, the resin RE may be cured by irradiating the resin RE with ultraviolet rays using the ultraviolet lamp UL. By way of example, since the resin RE is exposed upwardly, direct irradiation of the ultraviolet rays may be readily performed, thereby reducing a time required for curing the resin RE. The cured resin RE may correspond to the above-described reinforcing layer RL (refer to FIG. 2). Step S500 may be performed when the resin RE is an ultraviolet curable resin (UV resin). For example, step S500 may be omitted according to a type of the resin RE.

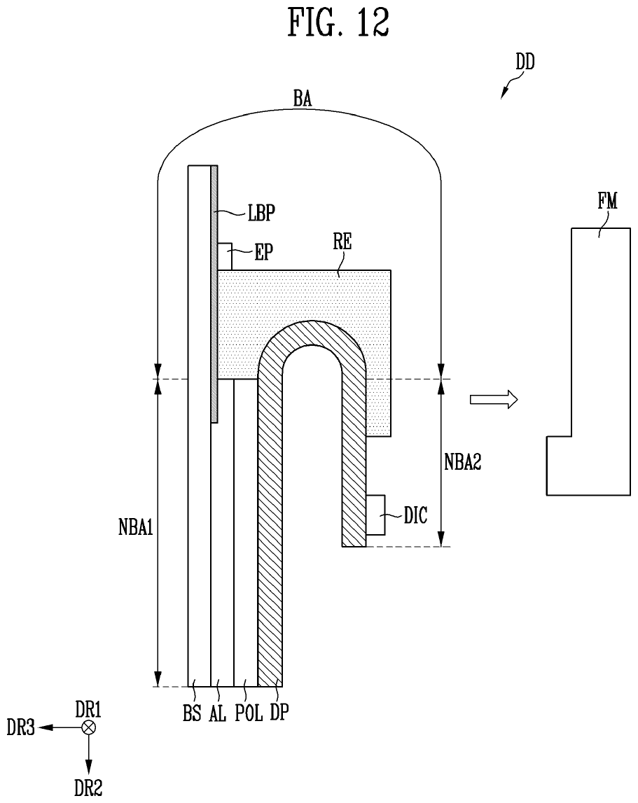

Referring to FIGS. 3 and 12, the fixing member FM may be detached from the display panel DP (S600). As described above, since the fixing member FM is formed of a material having releasability with the resin RE, the fixing member FM may be readily attached or detached without affecting the shape of the resin RE.

Although the disclosure has been described according to the above-described embodiments, it should be noted that the above-described embodiments are for describing the disclosure and not for limiting the scope of the disclosure. Those of ordinary skill in the art to which the disclosure pertains will understand that various modifications are possible within the scope of the technical spirit of the disclosure.

The scope of the disclosure is not limited to the details described in the detailed description of the specification, but should also be defined by the claims. It is to be construed that all changes or modifications derived from the meaning and scope of the claims and equivalent concepts thereof are included in the scope of the disclosure.

What is claimed is:

1. A display device comprising:
a display panel including:
a first non-bending area;
a bending area extending from the first non-bending area; and
a second non-bending area extending from the bending area;
an adhesive layer disposed in the first non-bending area;
a window connected to the display panel through the adhesive layer, the window including:
a base substrate;
a light blocking pattern disposed on the base substrate; and
a protrusion pattern disposed on at least a portion of the light blocking pattern; and
a reinforcing layer surrounding at least a portion of the bending area.

2. The display device according to claim 1, wherein the reinforcing layer contacts at least a portion of the light blocking pattern.

3. The display device according to claim 1, wherein the reinforcing layer contacts a surface of the protrusion pattern.

4. The display device according to claim 1, wherein the reinforcing layer contacts at least a portion of the first non-bending area.

5. The display device according to claim 1, wherein the reinforcing layer includes an ultraviolet curable resin.

6. The display device according to claim 1, wherein the protrusion pattern and the light blocking pattern include a same material.

7. The display device according to claim 1, wherein the protrusion pattern includes an ultraviolet curable resin.

8. The display device according to claim 1, wherein the light blocking pattern overlaps the bending area.

9. A method of manufacturing a display device, the method comprising:
providing a display panel including a first non-bending area, a bending area extending from the first non-bending area, and a second non-bending area extending from the bending area;
connecting a window to the display panel, wherein the window includes a base substrate, a light blocking pattern disposed on the base substrate, and a protrusion pattern disposed on at least a portion of the light blocking pattern to the display panel;
attaching the second non-bending area to a fixing member to upwardly expose the bending area;
applying a resin to surround at least a portion of the bending area; and
detaching the fixing member.

10. The method according to claim 9, wherein in the applying of the resin, the resin contacts at least a portion of the light blocking pattern.

11. The method according to claim 9, wherein in the applying of the resin, the resin contacts a surface of the protrusion pattern.

12. The method according to claim 9, wherein the light blocking pattern overlaps the bending area.

13. The method according to claim 9, wherein the protrusion pattern is formed by printing a same material as the light blocking pattern after the light blocking pattern is formed.

14. The method according to claim 9, wherein the protrusion pattern is formed by printing a same material as the light blocking pattern in which a portion of the light blocking pattern is masked.

15. The method according to claim 9, wherein the protrusion pattern is formed by applying the resin to the light blocking pattern and curing the resin with ultraviolet rays.

16. The method according to claim 9, wherein a portion of the fixing member to which at least a portion of the second non-bending area is attached protrudes.

17. The method according to claim 9, wherein the fixing member is formed of a material having releasability with the resin.

18. The method according to claim 9, wherein the fixing member is an open jig.

19. The method according to claim 9, wherein the fixing member is a guide film.

20. The method according to claim 9, further comprising:
curing the resin with ultraviolet rays.
